(19) United States
(12) Patent Application Publication
(10) Pub. No.: US 2007/0031587 A1
(43) Pub. Date: Feb. 8, 2007

(54) Manufacturing method of an organic electroluminescence device

(76) Inventors: Koji Takeshita, (US); Takahisa Shimizu, (US); Hironori Kawakami, (US)

Correspondence Address: SQUIRE, SANDERS & DEMPSEY L.L.P., 1 MARITIME PLAZA, SUITE 300, SAN FRANCISCO, CA, 94111, US

(21) Appl. No.: 11/371,396

(22) Filed: Mar. 8, 2006

(30) Foreign Application Priority Data
Aug. 3, 2005 (JP) 2005-063434

(51) Int. Cl. B05D 5/12; B05D 5/00

(52) U.S. Cl. 427/64; 427/256

(57) ABSTRACT

An organic electroluminescence device manufacturing method is disclosed wherein the device comprises a substrate, a first and second electrode, and an organic luminous layer. The method comprising: hardening of a water development type photosensitive resin to form a plastic plate; and printing organic luminescent ink on a substrate by relief printing method with the use of the plastic plate, wherein the organic luminescent ink is an ink capable of scattering organic luminescent material in an organic solvent.

### CROSS REFERENCE

This application claims priority to Japanese application number 2005-063434, filed on Mar. 3, 2005, which is incorporated by reference.

### BACKGROUND OF THE INVENTION

1. Field of the Invention

The present invention is related to process of manufacture an organic electroluminescence device including an organic luminescent material in a luminous layer.

More particularly, the present invention is related to process of manufacture an organic electroluminescence device by means of relief printing method.

2. Description of the Related Art

An organic electroluminescence device has an organic luminous layer including organic luminescent material between two opposed electrodes. It emits light by electric current to the organic luminous layer. Film thickness of the luminous layer is important, and it is necessary to make the film of around 100 nm to emit light efficiently. Even more particularly, it is necessary to form the luminous layer thin to make a display unit.

The organic luminescent material in the organic luminous layer can be made from low molecular materials and polymer materials. Generally a mask of a minute pattern is used, and the low molecular material is formed into a film by vaporization method using resistance heating. When a substrate for formation of thin film upsizes, in resistance heat coating by vaporization method, accuracy of the pattern becomes worse. Thus polymer materials is applied to organic luminescent material.

The coating liquid includes organic luminescent material dissolved in a solvent. Thin film formation by the wet coating method that use this coating liquid has been tried. Wet coating method for the thin film formation can be performed by spin coat method, bar coat method, lobe coat method and dip coat method. But in the wet coating method, it is difficult to form a pattern with high accuracy. In addition, it is difficult to divide into three colors of RGB when RGB liquids are coated.

By a printing method, a divided pattern can be formed easily. So, it is thought that thin film formation by a printing method is more effective.

As for the organic electroluminescence device, it is often that a glass substrate is used as a substrate supporting electrodes. Therefore method to use metal hard printing plate like photogravure process is unsuitable. Offset printing method which utilizes a blanket made of rubber having an elasticity and relief printing method to use resins such as rubber having an elasticity or a photosensitive resin as printing plate are desirable. As attempt by these printing methods, an approach (Japanese Patent Laid-Open No. 2001-93668 Official Gazette) by offset printing, and an approach (Japanese Patent Laid-Open No. 2001-155858 Official Gazette) by relief printing are proposed.

In offset printing, ink is attached to the printing plate on which pattern is formed. Pattern of the ink is put from printing plate to a blanket. Even more particularly, it is a printing method to form pattern of ink on substrate by putting an ink pattern into substrate from a blanket.

A blanket used for transfer of ink should be elastic. Generally a blanket made of rubber is used. As for the type of rubber used as a blanket, there are various rubbers such as olefinic type or silicone type. All these rubber have a property that is easy to be swelled and modified against aromatic type organic solvent such as a toluene, dimethylbenzene, and the like.

Relief printing method uses the printing plate having an image area that is convex shaped. Relief printing method holds ink in this convex part. Relief printing method puts ink from the convex part to a substrate.

Conventionally, a metal such as lead has been used as a material of printing plate. In late years a cheap, light photosensitive resin has been used. In addition, as an example of relief printing method, there is flexography with the use of rubber and a photosensitive resin as a material of printing plate.

In present specification, printing plate of relief printing with the use of these photosensitive resin is referred to as plastic plate.

A manufacturing process of photosensitive resin relief printing used by relief printing method is described below.

At first, a layer stack of a layer of a photosensitive resin is laminated by a substrate such as polyester film of good dimensional stability. Subsequently, a photosensitive resin is exposed through the mask. A light transmits only in a streak part, and streak region is rigidified. And photosensitive resin relief printing plate can be obtained by washing away an unexposed non-hardened zone with liquid developer such as solvent.

Depending on development mode, there are mainly two kinds of photosensitive resins: photosensitive resin which can be developed with organic solvent; and Photosensitive resin which can be developed with water.

Plastic plate of an organic solvent development type has been mainly used in general commercial printing, so-called flexographic printings for cardboard and flexible packaging materials. Ink used in a flexographic printing is mainly a water type, or an alcohol type ink. The printing plate should resist water type or alcohol type ink.

Development of a photosensitive resin for printing plate of the water development type that can get a high quality printed matter progresses. In the case of water development type, load to environment decreases, and a work situation improves.

As for these photosensitive resins, swelling/modification is not generated against ink of a water type/alcohol type.

On the other hand, organic solvent waste water is drained in development of a photosensitive resin of a solvent development type. A water development type can reduce discharge of organic solvent waste water. Development of a resin of a water development type aims at reduction of environmental load.

Polymer type organic luminescent material does not dissolve well in organic solvent of a water type, or alcohol type. In addition, organic solvent of a water type, or alcohol type gives luminescence property harmful effects.

Polymer type organic luminescent material should be dissolved in organic solvent of ink applied to coating and printing.

As for the organic solvent, aromatic organic solvent such as toluene or dimethylbenzene is preferred. Thus, ink of organic luminescent material can include an aromatic organic solvent.

As for the offset printing of one of the printing methods that are optimum as patterning of organic luminescent ink, the blanket is weak to the organic solvent. In addition, architecture of the blanket is complicated, and there are many problems that need to be addressed.

### SUMMARY OF THE INVENTION

In one embodiment of the invention an organic electroluminescence device manufacturing method is provided, wherein the device comprises a substrate, a first and second electrode, and an organic luminous layer. The method comprises hardening of a water development type photosensitive resin to form a plastic plate; and printing organic luminescent ink on a substrate by relief printing method with the use of the plastic plate, wherein the organic luminescent ink is an ink capable of scattering organic luminescent material in an organic solvent. In some embodiments, the organic electroluminescence device can include a partition wall sectioning the organic luminous layer. In some embodiments, the height of the partition wall is from 0.5 μm to 5 μm. In some embodiments, the plastic plate includes polyvinyl alcohol, polyurethane or polyamide.

Process of manufacture of the organic electroluminescence device which organic luminous layer is formed by a printing method with the use of organic luminescent ink including an organic solvent is provided in the present invention. Aromatic organic solvent is used as organic solvent in particular. And the present invention aims at providing the method that can form organic luminous layer of a minute pattern at high accuracy, high production efficiency in extended period.

When organic luminous layer was formed on a substrate and electrodes by a printing method to utilize organic luminescent ink, we found a possibility to be able to solve an above problem by relief printing method with the use of photosensitive resin relief printing of a water development type. In other words an unexposed section minute is washed away with water in development.

A water development type photosensitive resin is made of a material including a high content of hydrophilic components. Thus, resistance is high against an organic solvent.

We found that a desired organic luminous layer pattern was provided.

### BRIEF DESCRIPTION OF THE DRAWINGS

FIGS. 1A and, B illustrate a cross section of an organic electroluminescence element produced by process of manufacture of one embodiment the present invention.

FIG. 2 is a scheme which shows an example of a relief printing apparatus used in the present invention.

FIG. 3A shows the layer stack that a photosensitive resin that is held by the support medium which is polyester film. Surface is protected by means of the protective layer which is polyester film.

FIG. 3B shows a process to expose uniformly to a layer stack from the support medium side. Relief depth is decided.

FIG. 3C shows a process making relief of printed image. A protective layer is torn off. Negative film is affixed in the surface of a photosensitive resin. And it is exposed.

FIG. 3D shows a development process forming relief. Negative film is removed. An unexposed section is washed away by means of high pressure water.

FIG. 3E shows cross section of plastic plate used in the present invention typically.

### DESCRIPTION OF THE PREFERRED EMBODIMENTS

### Plastic Plate

An embodiment of the present invention uses a water development type photosensitive resin. At first a necessary part of a water development type photosensitive resin is stiffened by pattern exposure. Next, a part of the unnecessary, unexposed, non-hardened resin is washed away by water. Such a water development type photosensitive resin is based on water soluble resin. Any well-known water development type photosensitive resin can be used. For example, the type that include hydrophilic polymers, principal monomer including unsaturated bonding and a photoinitiator, can be used. Representative examples include polyamide, polyvinyl alcohol, polyurethane, or a cellulose derivative. In addition, for example, methacrylate having vinyl bond is exemplified for principal monomer including unsaturated bonding. For example, aromatic carbonyl compound is exemplified for photoinitiator.

In some embodiments, a water development type photosensitive resin including polyamide type polymer is preferred for printability.

The water development type photosensitive resin has been developed in consideration of environmental load and effects. Solvent of ink serving for general printing for cardboard and flexible packaging materials is generally water and alcohol. As for the high hydrophilic water development type plastic plate, resistance properties are low against such ink. Printing plate swells at the time of printing, and it can be transformed. High hydrophilic water development type plastic plate is inferior to the durability of printing. The difficulty is maintaining the balance between hydrophilia and hydrophobia. In other words there was a limit for improvement of water solubility. However, organic luminescent ink used in the present invention includes organic solvent.

If a hydrophilic property of plastic plate is high, the affinity with respect to an organic solvent is low. Moreover, the resistance property with respect to organic luminescent ink rises.

Coexistence of development suitability and the ink resistance properties is easy.

Organic luminescent ink used in process of manufacture of an organic electroluminescence device of the present invention includes an organic solvent.

Solubility parameter (the following, SP value) of a toluene representing organic solvent of particularly preferred aromatic type is 8.9, and SP value of dimethylbenzene is 8.8. By comparison, SP value of polyamide (nylon) is 13.6, and SP value of polyvinyl alcohol is 12.6, and SP value of cellulose is 15.7.

It has been found that a water development type photosensitive resin comprising these hydrophilic polymers has enough resistance properties for toluene or dimethylbenzene because SP value of polyamide, polyvinylalcohol and the like is different from SP value of toluene or dimethylbenzene.

The expansion coefficient when plastic plate used for the present invention is dipped in toluene or dimethylbenzene for 24 hours is less than 5%. Thus, swelling and modification of plastic plate are reduced when organic luminous layer is printed by relief printing method consecutively for a long time. So, a desired pattern can be achieved.

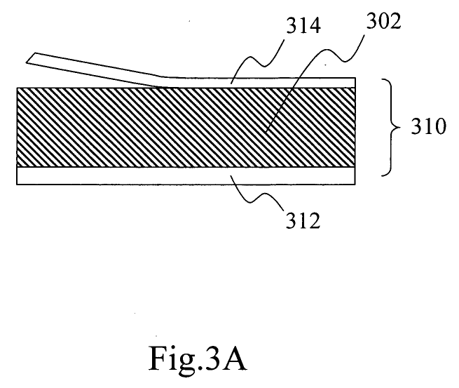

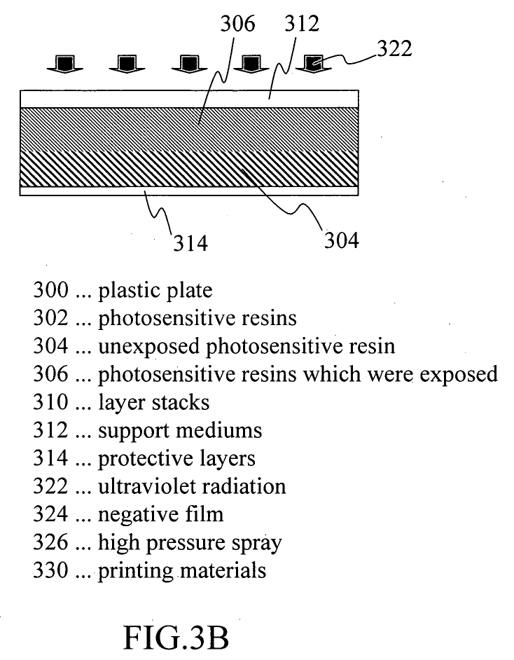

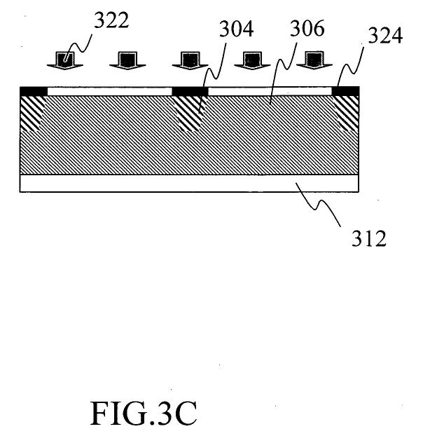

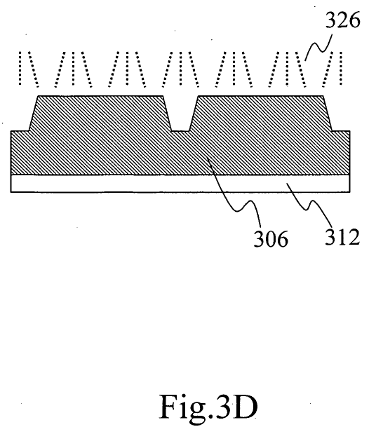

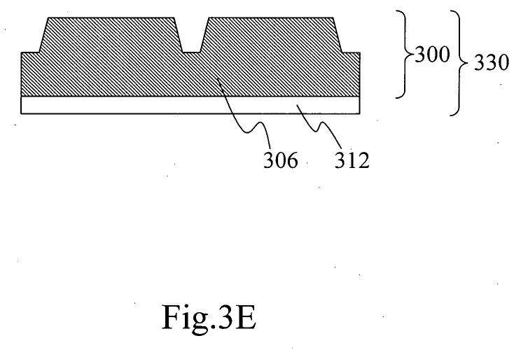

It is a printing material that plastic plate 300 was added to support medium 312. At the time of relief printing, a printing material is mounted on a plate cylinder (cylinder). A polyester seat, a steel plate, aluminum board are exemplified for support medium 312. Cf. FIG. 3E.

### Manufacture of Plastic Plate

In some embodiments the plastic plate used for the present invention is produced as follows:

Layer stack 310 is prepared. As illustrated by FIG. 3A, layer stack 310 includes support medium 312 of a polyester film holding water development type photosensitive resin 302 and a protective layer 314 of polyester film. Support medium 312 is clear or transparent. Ultraviolet radiation 322 is uniformly irradiated to layer stack 310 from support medium 312 side, and it is exposed, as best illustrated by FIG. 3B. A, negative film 324 is stuck on surface of the photosensitive resin where protective layer 314 was torn off. As illustrated in FIG. 3C Ultraviolet radiation 322 is irradiated, and “relief” of printed image is made (the main exposure).

Negative film 324 is removed. In some embodiments, unexposed photosensitive resin 304 is washed away by water. Relief or a printed pattern is formed or developed.

In the washout step, in some embodiments, brush cleaning can be performed. In yet other embodiments, blow method of exposed photosensitive resin surface by a photographic developer using high pressure spray 326 can be conducted. Cleaning method by high pressure spray is shown in FIG. 3D.

In process of manufacture of the present invention, organic luminous layer formed by printing can be very thin. In some embodiments, it can be less than 100 nm). A minute pattern, such as a pattern distance of 30-100 μm and a pattern size of several hundred μm can be formed.

Cleaning method by the high pressure spray which can finish plastic plate surface uniformly is preferred. In addition, cleaning method with the use of a brush is preferred.

After development, a solvent, which a photosensitive resin absorbs and is dried, is removed. In some embodiments, the solvent can be water or a majority of the solvent (w/w) can constituted water.

It is appreciated by one having ordinary skill in the art that surface treatment and after-exposure can be performed if necessary.

Plastic plate 300 used for the present invention can be made according to the described methodology, as illustrate by FIG. 3E.

### Adjusting of Organic Luminescent Ink

An organic electroluminescence device of an embodiment of the present invention includes a substrate, a first electrode, an organic luminous layer, and the second electrode. The sequence can be as is listed.

Organic luminous layer includes an organic luminescent material.

The organic luminescent material can include low molecular type organic luminescent material and high molecular form organic luminescent material. Representative embodiments of low molecular type luminescent materials include the following:

9,10-diaryl anthracenes, pyrene, coronene, perylene, rubrene, 1,1,4,4-tetra phenylbutadiene, tris(8-quinolinolate)aluminium complex, tris(4-carbinyl-8-quinolinolate)aluminium complex, bis(8-quinolinolate)zinc complex, tris(4-carbinyl-5-trifluoromethyl-8-quinolinolate)aluminium complex, tris(4-carbinyl-5-cyano-8-quinolinolate)aluminium complex, bis(2-carbinyl-5-trifluoromethyl-8-quinolinolate)[4-(4-cyanophenyl)phenolate]aluminium complex, bis(2-carbinyl-5-cyano-8-quinolinolate)[4-(4-cyanophenyl)phenolate]aluminium complex, tris(8-quinolinolate)scandium complex, bis[8-(para-tosyl)aminoquinoline]zinc complex and cadmium complex, 1,2,3,4-tetraphenylcyclopentadiene, the pentaphenyl cyclopentadiene, poly-2,5-diheptyloxi-para-phenylenevinylene, chroma phosphorus type fluorescent substance, the perylene type fluorescent substance, the pyran type fluorescent substance, the anthrone type fluorescent substance, the porphyrin type fluorescent substance, the quinacridon type fluorescent substance, N,N′-dialkyl displacement quinacridon type fluorescent substance, the naphthalimido type fluorescent substance, N,N′-diaryl displacement pyrrolo pyrrole series fluorescent substance, low molecular system luminescent material such as phosphorescence fluor such as Ir chelate, high polymer materials such as poly arylene type, poly arylenevinylene type, poly fluorene, polyparaphenylene vinylene, polythiophene, police pyro, the material which the low molecular material is dispersed in these high polymer materials, or the material which inter-polymerization of the low molecular material with these high polymer materials was done, the material which low molecular system luminescent material is scattered in high polymer materials such as polystyrene, polymethyl methacrylate, polyvinylcarbazole, existing macromolecule/low molecular luminescent material.

Organic luminescent material of low molecular type can be formed by vacuum processes such as coating by vaporization methods.

Same as organic luminescent material of high molecular form, ink can be made by dissolving organic luminescent material of low molecular type in an organic solvent.

If necessary, a resin is added in this ink to adjust to the viscosity that can be printed, and it can be used together with luminescent material of high molecular form.

Organic luminescent material is dissolved by an organic solvent and/or can be dispersed. It can be used for printing as organic luminescent ink.

For the organic solvent which can be applied for adjusting the organic luminescent ink, solvents such as a toluene, dimethylbenzene, acetone, anisole, methyl ethyl ketone, methyl isobutyl ketone, cyclohexanone or mixture or combination thereof can be used.

Preferably, in a point of solubility of organic luminescent material, aromatic organic solvent such as a toluene, dimethylbenzene, and/or anisole can be used.

### Organic Electroluminescence Device

One embodiment of an organic electroluminescence device and the process of manufacture is discussed below.

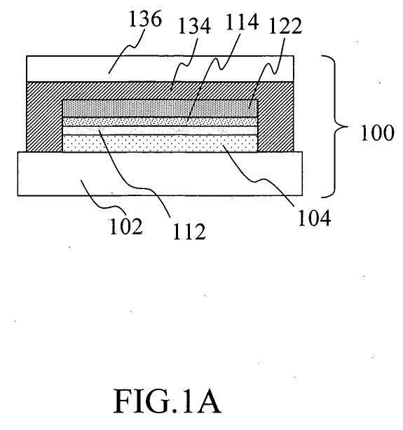

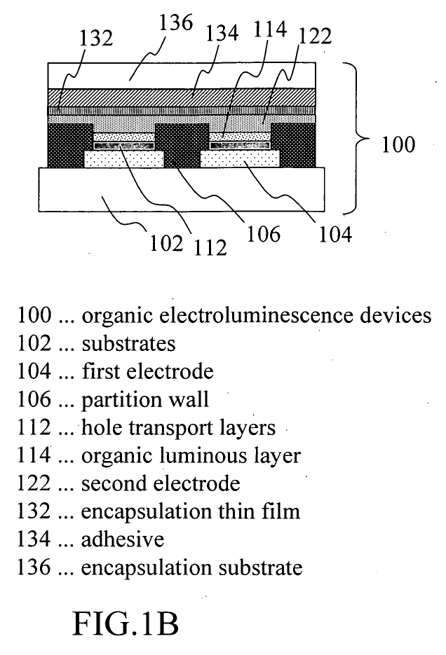

As is best illustrated by FIGS. 1A and B, organic electroluminescence device 100 of one embodiment of the present invention includes a substrate 102, a first electrode 104, a organic luminous layer 114, and a second electrode 122. For example, as for the substrate from which the organic luminous layer 114 is formed, transparent electrode corresponding to the first electrode 104 is formed on the substrate. In addition, macromolecular hole transport layer 112 can be formed thereon.

A glass substrate can be used as substrate 102 of an organic electroluminescence device. If substrate 102 can hold electrode, organic luminous layer or a seal, metal substrate and resin substrate can be used. Should a resin substrate be used, by reason of prevention of degradation of organic luminous layer and electrode, a resin substrate that prevents transmission of oxygen and humidity is desirable.

In some embodiments, indium-tin oxide (ITO) film can be exemplified for the transparent electrode. A dry process sputter method can be used to form the transparent electrode.

FIG. 1 shows cross section of an organic electroluminescence device. The first electrode 104 in a form of non-pattern is made. There is no partition wall. The transparent electrode can be patterned by a photo-etching method with the use of a photosensitive resin, if necessary.

In one embodiment, in the case of an organic electroluminescence device of passive matrix drive, transparent electrode is formed in the shape of a stripe. A substrate may include partition wall 106 corresponding to a picture element. Partition wall sections each picture element comprising an organic electroluminescence device. Partition wall coats an edge of pattern-shaped first electrode. This is to prevent a short circuit between the first electrode and the second electrode.

FIG. 1B illustrates cross section of an organic electroluminescence device in accordance to one embodiment. A pattern of the first electrode 104 is formed. Partition wall 106 can cover an edge of the first electrode 104.

In some embodiments, resin coating fluid having photosensitivity and insulating properties is put on a substrate provided with the first electrode. A region corresponding to a pattern of predetermined partition wall is exposed. Partition wall can be made by developing methods.

The process of an embodiment of the present invention forms a pattern by means of a printing method. Therefore, a color mixture and white coming out can be prevented when height of partition wall is 0.5 μm-10 μm. In addition, organic luminescent ink can be filled in a region sectioned by partition wall. And a color mixture and white coming out can be prevented sufficiently at the time of manufacture because ink is filled with a region sectioned in partition wall of height of 0.5 μm-10 μm by a printing method. In addition, the step between partition wall and picture element parts is small when second electrode and a layer for encapsulation are laminated to form an organic electroluminescence device. Therefore, yield of manufacture of an organic electroluminescence device is high. In addition, the organic electroluminescence elements having a long life-time can be produced.

In addition, as a substrate, the thin film transistor (TFT) substrate which includes a thin film transistor (TFT) corresponding to each picture element on a substrate and an insulator layer coating TFT and pixel electrodes (first electrode) of form of pattern corresponding to each picture element can be used. For this case, it is desirable to form partition wall in a form of a grating to cover an end of pixel electrodes.

Organic electroluminescence device 100 of one embodiment of the present invention can include organic luminous layer 114 between the first electrode 104 and the second electrode 122. By reason of improvement of luminous efficiency, any one of a hole implant layer, a hole transport layer, electronic blocking layer, a buffer layer, hole blocking layer, an electron transporting bed, an electron injection layer may also be included. These components can be, collectively or in specific combinations, referred to as a luminescent assistance layer.

For example, as a pair of a luminescent assistance layer and organic luminous layer, assembly (1) of hole transport layer 112 and organic luminous layer 114 can be exemplified (FIGS. 1A and 1B)

In addition, assembly (2) of a hole transport layer and organic electron transport property luminous layer or organic hole transport-related luminous layer can be exemplified.

In addition, assembly (3) with a hole transport layer and organic luminous layer and electron transport layer can be exemplified.

One layer can serve as plural functions such as hole transport and a luminescent. Representative examples of a hole transport material, comprising a hole transport layer, include copper phthalocyanine, Metallophthalocyanine such as tetra(t-butyl) copper phthalocyanine, Metal-free phthalocyanine, Quinacridon chemical compound, aromatic amine type low molecular hole injection transportation material such as N,N′-di(1-naphthyl)-N,N′-diphenyl-1,1′-biphenyl-4,4′-diamine, 1,1-bis(4-di-p-tolylamino phenyl)cyclohexane, N,N′-diphenyl-N,N′-bis(3-methylphenyl)-1,1′-biphenyl-4,4′-diamine, macromolecule hole transport materials such as polyaniline (PANI), polythiophene, polyvinylcarbazole, mixture with poly (3,4-ethylenedioxy thiophene) (PEDOT) and polystyrene sulfonate, polythiophene oligomer material, and other existing hole transport materials.

Various coating method can be used for the formation of a hole transport layer. By way of example only, the spin coat method having a wet processes, a printing method and ink jet method can be used. For some embodiments of the present invention, a water system is preferable for a solvent.

Representative examples of an electron transport material include 2-(4-biphenyl)-5-(4-t-butylphenyl)1,3,4-oxadiazole, 2,5-bis(one-naphthyl)-1,3,4-oxadiazole, Oxadiazoles, Bis(ten-hydroxybenzo[h]quinolinate)beryllium complex, Triazole compound, and combinations thereof.

As is understood by one having ordinary skill in the art, a vacuum deposition can be for the deposition of these materials.

In addition, a luminescent assistance layer can be formed by wet process and dry process depending on the material.

Total film thickness with a luminescent assistance layer and organic luminous layer can be lower than 1,000 nm, and preferably it is 50-150 nm.

As for the hole transport material of an organic electroluminescence device, covering of the surface protrusions of the substrate and first electrode is particularly important. Therefore, it is preferable to form a film of around 50-100 nm.

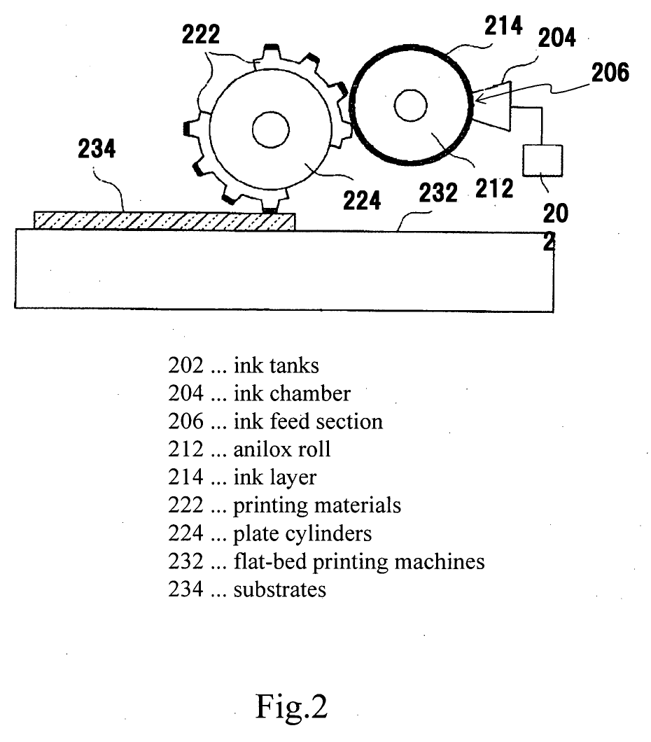

FIG. 2 illustrates a schematic illustration of a relief printing apparatus when a pattern printing of organic luminescent ink including an organic luminescent material is performed on the substrate that includes a transparent electrode and a hole transport layer.

This manufacturing apparatus has ink tank 202, ink chamber 204, anilox roll 21 and plate cylinder 224 on which printing material 222 is placed. Printing material 222 includes plastic plate. Organic luminescent ink including an organic solvent is taken to ink tank 202. Organic luminescent ink is transferred into ink chamber 204 from ink tank 202. Anilox roll 212 makes contact with ink feed section 206 of ink chamber 204, as it is rotatably supported.

With a rotation of anilox roll 212, ink layer 214 of organic luminescent ink supplied in anilox roll surface is formed with uniform thickness. Ink of the ink layer is moved to a convex part of printing material 222 in plate cylinder 224 by being rotationally driven in proximity to anilox roll.

Substrate 234 having the transparent electrode and a hole transport layer formed therein is transported to flat-bed printing machine 232 by a transporting means that is not illustrated. Ink in the convex part of printing material 222 is printed onto substrate 234. Thickness of organic luminous layer formed in this way can be 50 nm-100 nm, and preferably can be 50 nm-80 nm.

In addition, the processes can be performed multiple times. Inks including the organic luminescent materials which emit lights in a different color respectively can be used. Accordingly, organic electroluminescence elements of color display can be produced.

In some embodiments, relief printing method with the use of water development type plastic plate can be used for formation of a luminescent assistance layer with the use of coating fluid including an organic solvent.

Second electrode 122 can be formed next as illustrated by FIGS. 1A and 1B. When second electrode is cathode formed on organic luminous layer 114 and electron transport layer, the material discussed below can be used.

The material can be of a type with high electron injection efficiency to a luminescent assistance layer and low work function. In some embodiments, the luminescent assistance layer can be the electron transport layer.

In some embodiments, second electrode 122 can include a metal such as Mg, Al, Yb and combination of the same.

In addition, the following layer stack may be put in a boundary surface of the luminescent medium. The layer stack is that with chemical compound of about 1 nm thicknesses such as Li and oxidation Li, LiF and Al and Cu of stability and/or high conductivity. Stability should be balanced with electron injection efficiency. Therefore an alloy system may be used. Alloy of more than one kind of metal such as Li, Mg, Ca, Sr, La, Ce, Er, Eu, Sc, Y and Yb that have a low work function, and metallic element such as Ag, Al, and Cu which are stable can be used. In some embodiments, alloy such as MgAg, AlLi, and CuLi can be used.

It is desirable to select a material having translucency in so-called top emission construction so as to allow visible radiation to come out of the second electrode side. In this case, Li and Ca of a low work function are provided with thin measurements. Metal complex oxide such as ITO (indium tin complex oxide) and indium zinc complex oxide, zinc aluminium complex oxide may be laminated thereafter. In addition, a little metal doping such as Li and Ca of a low work function can be performed to organic luminous layer 114, and metal compound such as ITO may be laminated.

Depending on the material, for the formation of the second electrode, methods such as resistance heat coating by vaporization, electron beam evaporation, reactive deposition, ion plating, sputtering can be used.

For the second electrode, thickness of about 10 nm-1,000 nm is desirable to secure enough ohmic value.

In addition, thin second electrode can be used to keep translucency when second electrode is used as translucency electrode layer. When metallic substances such as Ca, Ba or Li are used, in the case of low translucency, the thickness can be around 40 nm. However, in the case of high translucency, thickness can be equal to or less than 30 nm. Most preferably, it is equal to or less than 20 nm.

Higher than 10 nm are desirable for thickness to secure ohmic value as electrode, in addition, to maintain configuration as film.

When translucency conductive metal chemical compound such as ITO is used as second electrode, thickness of 10 nm-300 nm are desirable to secure the desired ohmic value.

When damage to a lower organic luminescent medium layer at laminating is considered, the thickness is preferred to be lower than 100 nm.

Both thin films of metal and metal compound are laminated, and it may be used as second electrode.

Even more particularly, metal compound materials such as LiF may be used as one part of second electrode. In some embodiments, metal compound materials such as LiF may be laminated in the layer which is next to second electrode.

In organic electroluminescence device, organic luminous layer can be sandwiched between electrodes, and it can emit light by applied electric current. However, organic luminous layer can easily deteriorate by exposure to atmospheric moisture and oxygen. Thus a seal to intercept organic luminous layer from the such conditions can be provided. For example, encapsulation substrate 136 is adhesively bonded with adhesive 134, which can be provided as a seal (see FIG. 1A).

A seal can be made by including on the second electrode side a encapsulation thin film 132, as illustrated by FIG. 1B.

For encapsulation of thin film 132, inorganic thin film can be used. By way of example only, silicon-nitride film of thickness 150 nm can be formed on the second electrode directly by CVD method. It is preferable that the encapsulation be completed only with encapsulation thin film. Simplification of a manufacturing process of an organic electroluminescence device is possible. In addition, an organic electroluminescence device can be made thinly.

However, performance of the present encapsulation thin film is not ideal. Therefore, from a point of emission lifetime, encapsulation substrate should be used together with encapsulation thin film.

For the adhesive 134, the following adhesive can be used: A photo-curing adhesive property resin, a heat curing adhesive property resin, 2 fluid hardening adhesive property resins comprising an epoxy type resin, acrylic resin, silicone oil and the like, acrylic resin such as ethylene ethylacrylate (EEA) polymer, vinyl resins such as ethylene vinyl acetate (EVA), thermoplastic resin such as polyamide, a synthetic rubber, and thermoplasticity adhesive property resins such as acid denatured substances of polyethylen or polypropylene.

Methods of forming the adhesive layer on second electrode 122 or encapsulation thin film 132 include solvent solution method, “pushing out” laminate method, fusion/hot melt method, calender method, discharge jet application method, screen printing, vacuum laminate method, and heated roll laminate method.

A resin of ultraviolet cure type is used, and it is adhesively bonded by LTV radiation. Organic luminous layer is not heated. Therefore, heat degradation of organic luminous layer and the like can be prevented. In addition, an organic electroluminescence device is a layer stack of materials of various coefficients of thermal expansion. Therefore, modification of an organic electroluminescence device and layer-breaking can be prevented.

Luminescent material deteriorates by means of ultraviolet radiation. So, adhesive is placed not to fall on pixel areas emitting light. Masking means such as masks are used to cover a light emitting area on the occasion of irradiation of ultraviolet radiation.

A material having hygroscopicity and a property to absorb oxygen can be incorporated into adhesive if necessary.

Depending on size and configuration of sealed organic electroluminescence display unit, thickness of adhesive installed in a sealing medium can be fixed. As for the thickness of adhesive, about 5-500 μm is desirable.

Adhesive may be placed on the whole area of encapsulation substrate. In some embodiments, it may be formed in the shape of a frame to seal surroundings.

For encapsulation substrate 136, it is necessary for transmissivity of moisture and oxygen to be low. Humidity resistance film that can be used include ceramics such as alumina, silicon nitride, boron nitride, glass such as no-alkali glass, alkali glass, quartz, and metallic foil such as aluminium or stainless.

In some embodiments, the following humidity resistance film can be used: A film which comprised SiOx by CVD method on both sides of a plastic substrate, the film which laminated the film that transmissivity of moisture and oxygen is small and hydrophilic film, and the film which water absorption agent is applied to on the film that transmissivity of moisture and oxygen is small.

It is preferable for water vapor permeation rate of a humidity resistance film to be less than 10⁻⁶ g/m²/day.

For configuration of encapsulation substrate, flat tabular, form of film or cap configuration as referred to as canned encapsulation are exemplified.

After having put adhesive to a second electrode side, encapsulation substrate can be adhesively bonded. In addition, after having put adhesive to an encapsulation substrate side, encapsulation substrate can be bonded to second electrode.

In some embodiments, the adhesive is applied to a whole area of the encapsulation substrate side.

Subsequently, second electrode of an organic electroluminescence device can be affixed to encapsulation substrate under vacuum or dry inert gas environment.

When it is two levels of construction with encapsulation substrate and adhesive of thermoplastic resin, contact bonding should be performed only by a heating roller.

In that case of a heat curing type adhesion resin, it attaches by pressure by heating roller. A heat curing type adhesion resin is heated, and is hardened.

At first, in the case of a photo-curing-related adhesion resin, it is sealed by roll pressure. And a photo-curing-related adhesion resin is stiffened by irradiating a light.

By means of the above-mentioned process, an organic electroluminescence device can be produced.

When organic luminous layer is formed by relief printing method, swelling/modification of plastic plate by organic solvent included by organic luminescent ink is reduced in process of manufacture of the present invention.

Organic luminescent ink is printed at high accuracy and with high production efficiency in extended period.

When an organic electroluminescence device is used as a color display in particular, minute pattern corresponding to each picture element can be printed with high accuracy/high performance.

### EXAMPLE 1

Thin film of an indium-tin oxide (ITO) which was first electrode was formed to a glass substrate. The first electrode was configuration of stripe. Length of stripe was 33 mm. Line width of stripe was 126 μm. There were 192 stripes, and line space was 40 μm. This was a size of a passive matrix type display unit of diagonal 1.8 inches.

Subsequently coating liquid was applied to the glass substrate by a spin coating, which formed stripe-shaped first electrode. And the unnecessary region which was not necessary for a luminescent was wiped, and it was removed. And drying by heating was done, and, in this way, a hole transport layer was formed. The coating liquid was the coating fluid which dissolved 3,4-polyethylenedioxithiophene (PEDOT) as a hole transport material in pure water. The substrate that organic luminous layer would be printed was prepared in this way.

For organic luminescent ink, the liquor which dissolved the polyphenylene vinylene derivative which was organic luminescent material in a toluene was used.

The printing material comprising water development type plastic plate for printing of organic luminous layer was made as follows.

The layer stack that a water development type polyamide photosensitive resin was laminated by PET film support was prepared for.

A negative film mask to form predetermined streak was put on the surface of the photosensitive resin of this layer stack.

Ultraviolet radiation was irradiated by exposure equipment through a mask to surface of a photosensitive resin, and a streak part was stiffened.

An ultraviolet radiation transmission part was formed in this negative film mask to shade the light in non-streak part. Length of an ultraviolet radiation transmission part was 33 mm. Line width of an ultraviolet radiation transmission part was 126 μm. There are 64 ultraviolet radiation transmission parts, and the space is 372 μm.

The negative film mask was removed next.

The layer stack was washed in tap water with a brush. A non-hardened zone was washed away, and a streak part was formed.

As for the layer stack developed in this way, it was dried. Moisture was removed.

And afterexposure of a whole area was done by means of exposure equipment again.

A printing material to be employed for an example was got.

This printing material was put on a plate cylinder of a relief printing apparatus. A relief printing apparatus is shown in FIG. 2 typically. A relief printing apparatus was alined to match in the first electrode and a hole transport layer installed in the substrate. And the ink was supplied in a convex part of plastic plate by anilox roll. Organic luminous layer was printed. Organic luminous layer of thickness 80 nm printed to a glass substrate having ITO electrode layer and a hole transport layer was got.

Evaluation of pattern accuracy of this organic luminous layer is shown in table 1.

By vacuum evaporation using resistance heating method, aluminium of thickness 300 nm was formed in this substrate.

This aluminum layer was second electrode, and, in addition, it was cathode. Coating by vaporization of second electrode was performed through a metal mask. Second electrode was perpendicular to first electrode. Length of second electrode was 33 mm. Width of second electrode was 166 μm. There were 64 second electrodes.

A heat curing type resin and glass encapsulation cap were used, and an organic electroluminescence device was sealed last.

A passive drive type organic electroluminescence device of monochromatic specification of picture element number 4096 was made.

About plastic plate, a dipping experiment in a toluene was done for 24 hours. The swelling rate of silicone rubber relief printing plate was 153%. The swelling rate of butyl rubber relief printing plate was 103%. The swelling rate of solvent development type relief printing plate was 22%. The swelling rate of water development type relief printing plate was 0.01%.

Evaluation of emitting state of this organic electroluminescence device is shown in table 2.

### COMPARATIVE EXAMPLE 1

A printing material comprising solvent development type plastic plate for printing of organic luminous layer was made as follows.

The layer stack that a solvent development type photosensitive resin was laminated by PET film support was prepared. A negative film mask same as example 1 was used. It was exposed same as example 1, and a streak part was stiffened. A negative film mask was removed next. This layer stack was washed by means of a brush in organic solvent of hydrocarbon type. A non-hardened zone was washed away, and a streak part was formed. As for this layer stack, it was dried. Solvent was removed. Afterexposure was done in a whole area by means of exposure equipment again. A printing material to be employed for comparative example 1 was got.

Plastic plate of comparative example 1 was used, and organic luminous layer was printed by method same as example 1. Organic luminous layer of pattern-shaped thickness 80 nm was got to a glass substrate having ITO electrode layer and a hole transport layer. Evaluation of pattern accuracy of this organic luminous layer is shown in table 1.

Cathode was formed same as example 1. It was sealed by means of encapsulation cap. A passive drive type organic electroluminescence device of monochromatic specification of picture element number 4096 was made. Evaluation of emitting state of this organic electroluminescence device is shown in table 2.

### COMPARATIVE EXAMPLE 2

The printing material comprising rubber relief printing for printing of organic luminous layer was made as follows.

By means of an image formation method with the use of a computer, so-called computer to plate (CTP) method, a laser engraving of a seat of butyl rubber system was performed. Convex streak was formed in a rubber sheet. A printing material comprising rubber relief printing plate used in comparative example 2 was made by the above-mentioned process. Formed relief corresponds to pattern of the first electrode and the hole transport layer that a substrate includes. There were 64 stripes of 33 mm long, 126 μm wide. Space of stripe was 372 μm.

Using rubber relief printing of comparative example 2, organic luminous layer was printed same as example 1. Organic luminous layer of pattern-shaped thickness 80 μm was formed to a glass substrate having ITO electrode layer and a hole transport layer. Evaluation of pattern accuracy of this organic luminous layer is shown in table 1. Cathode was formed same as example 1. Encapsulation cap was used, and an organic electroluminescence device was sealed. A passive drive type organic electroluminescence device of monochromatic specification of picture element number 4096 was made. Evaluation of emitting state of this organic electroluminescence device is shown in table 2.

TABLE 1

| | Displacement (μm) | | | Increment of line width (μm) | | | | |
|---|---|---|---|---|---|---|---|---|
| | Number of times of printing | | | | | | | |
| | 1 | 50 | 100 | 1 | | 50 | | 100 |
| Example 1 | 0 | 3 | 7 | 0 | smaller | 0.1 | smaller | 0.1 |
| | | | | | than | | than | |
| Comparative | 0 | 33 | 50 | 0 | | 0.4 | | 1 |
| example 1 | | | | | | | | |
| Comparative | 5 | 140 | 320 | 0 | | 1 | | 2 |
| example 2 | | | | | | | | |

Displacement is explained. An outside line of the first electrode in one end is a reference line. Organic luminous layer is printed. Displacement width of an organic luminous layer printed pattern on the first electrode line in the other end is measured. This length is defined as displacement.

Increment of line width is increment from 166 μm that are line width of a printing material before printing.

TABLE 2

Number of times of printing

| | 1 | 50 | 100 |
|---|---|---|---|
| Example 1 | Excellent | Excellent | Good |
| Comparative | Excellent | Fair | Bad |

The device that the pixel that emitted light was under 80% is, Bad. The device that the pixel that emitted light was under 90% more than 80% is, Fair. The device that the pixel that emitted light was under 100% more than 90% is, Good. The device that the pixel that emitted light was 100% is, Excellent.

Result is shown in table 1. As for the pattern of organic luminous layer printed in example 1, accuracy with respect to a pattern of ITO electrode was preferable. Displacement was not observed, too. In addition, abnormality of printing plate surface was not observed by visual inspection, too. Increment of line width was not observed, too. Emitting state of the organic electroluminescence device made in example 1 was good.

On the other hand, the whole of pattern of organic luminous layer enlarged when printing number of times increased in comparative example 1 and comparative example 2. Displacement and distortion occurred. Increment of line width was long, too. Distortion of a line was observed by visual inspection. In addition, in comparative example 1 and comparative example 2, the organic electroluminescence device which was formed organic luminous layer by the first printing emitted light. However, in comparative example 1 and 2, the organic electroluminescence device which formed organic luminous layer by printing of the 50th and the 100th did not emit light almost.

What is claimed is:

1. An organic electroluminescence device manufacturing method, wherein the device comprises a substrate, a first and second electrode, and an organic luminous layer, the method comprising:
hardening of a water development type photosensitive resin to form a plastic plate; and
printing organic luminescent ink on a substrate by relief printing method with the use of the plastic plate, wherein the organic luminescent ink is an ink capable of scattering organic luminescent material in an organic solvent.

2. A organic electroluminescence device manufacturing method according to claim 1,
wherein the organic electroluminescence device includes partition wall sectioning organic luminous layer,
and wherein height of the partition wall is from 0.5 μm to 5 μm.

3. A organic electroluminescence device manufacturing method according to claim 1,
wherein the plastic plate includes polyvinyl alcohol, polyurethane or polyamide.
